(19) United States
(12) Patent Application Publication
(10) Pub. No.: US 2025/0233074 A1
(43) Pub. Date: Jul. 17, 2025

(54) METHODS FOR SELECTIVE METAL CAP FORMATION

(71) Applicant: Taiwan Semiconductor Manufacturing Company, LTD., Hsinchu (TW)

(72) Inventors: Chien Chang, Hsinchu (TW); Tai Min Chang, Taipei (TW); Bo-Wei Hsu, Taichung (TW); Yi-Ning Tai, Taoyuan (TW); Kan-Ju Lin, Kaohsiung (TW); Yu-Ming Huang, Tainan (TW); Chih-Shiun Chou, Hsinchu (TW); Harry Chien, Chandler, AZ (US); Chih-Wei Chang, Chu-Dong (TW); Ming-Hsing Tsai, Chu-Pei (TW)

(21) Appl. No.: 18/409,915

(22) Filed: Jan. 11, 2024

(51) Int. Cl. H01L 23/532; H01L 21/768; H01L 23/522; H01L 23/528

(52) U.S. Cl. CPC H01L 23/53266; H01L 21/76804; H01L 23/5226; H01L 23/5283; H01L 23/5329

(57) ABSTRACT

A molybdenum cap is formed upon a via to increase the contact area of the via in an interconnect structure. A hard mask layer is patterned to expose the via through a gap. The molybdenum cap is deposited upon the via using a mixture comprising a carrier gas and a molybdenum precursor. The mixture is adjusted so that molybdenum is not deposited upon the hard mask layer. As a result, the gap in the hard mask layer is not reduced in size and the thickness of the molybdenum cap can be increased, reducing the total resistance of the interconnect structure.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Thin film resistors can be made as part of such integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view showing a first example embodiment of an interconnect structure, in accordance with some embodiments.

FIG. 1B is a cross-sectional view of the interconnect structure of FIG. 1A, illustrating additional details of the various components.

FIG. 1C is a magnified cross-sectional view of the upper portion of the interconnect structure of FIG. 1A, illustrating additional details.

FIG. 2 is a flow chart illustrating a method for forming the resistor structure, in accordance with some embodiments. Various steps of this method are shown in FIGS. 3-10.

FIG. 3 is a cross-sectional view after patterning of a first dielectric layer to form bottom vias.

FIG. 4 is a cross-sectional view after patterning of a dielectric layer to form at least one via opening.

FIG. 5 is a cross-sectional view after filling of the via opening with an electrically conductive material.

FIG. 6 is a cross-sectional view after planarization of the electrically conductive material.

FIG. 7 is a cross-sectional view after addition of an etch stop layer, another dielectric layer, and a hard mask layer.

FIG. 8 is a cross-sectional view after patterning to expose the via through a gap in the hard mask layer.

FIG. 9 is a cross-sectional view after selective deposition of a molybdenum cap upon the via.

FIG. 10 is a cross-sectional view after deposition of a barrier diffusion liner.

FIG. 11 is a cross-sectional view after deposition of an electrically conductive material upon the molybdenum cap.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them.

The term “semiconductor die”, or “chip”, or “microchip” are used interchangeably in the present disclosure to refer to the combination of a substrate and the multiple layers upon the substrate which form one or more integrated circuits.

The term “semiconductor package”, as used in the present disclosure, refers to the combination of a semiconductor die and an interconnect layer. Examples of an interconnect layer may include a redistribution layer (RDL) or an interposer having bond pads or C4 bumps or pillars. Thus, a semiconductor package may have an interconnect layer on only one side, or on both sides. It is noted that in the art, the term “package” is used to refer to many different structures and does not have a single fixed definition.

The present disclosure relates to various methods for reducing the total interconnect resistance of an interconnect structure used in an interconnect layer that permits a semiconductor die to communicate with one or more other semiconductor packages. The resistance increases as device dimensions decrease, due to increased electron scattering. Approaches to reducing resistance include increasing the contact area of the vias in the interconnect structure without changing the critical dimension (CD) of the via. However, applying a cap to the via also affects the gapfill window for the subsequent step of applying an interconnect metal to the cap, because the material used to form the cap also deposits on the mask and reduces the width of the window. Because the interconnect metal is typically applied by a conformal deposition process, undesirable voids naturally form when the interconnect metal around the cap merge together. Generally, a smaller CD comes with a higher risk of incurring voids. In the methods of the present disclosure, the material used to apply a molybdenum cap to a molybdenum via does not deposit on the mask. As a result, the width of the gapfill window is not reduced. As a result, the via contact area can be maximized to lower the electrical resistance without increasing the risk of creating voids.

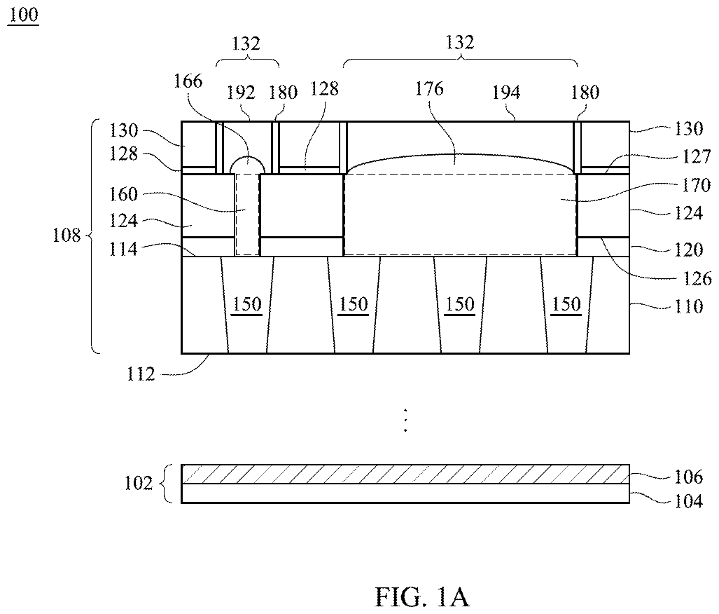

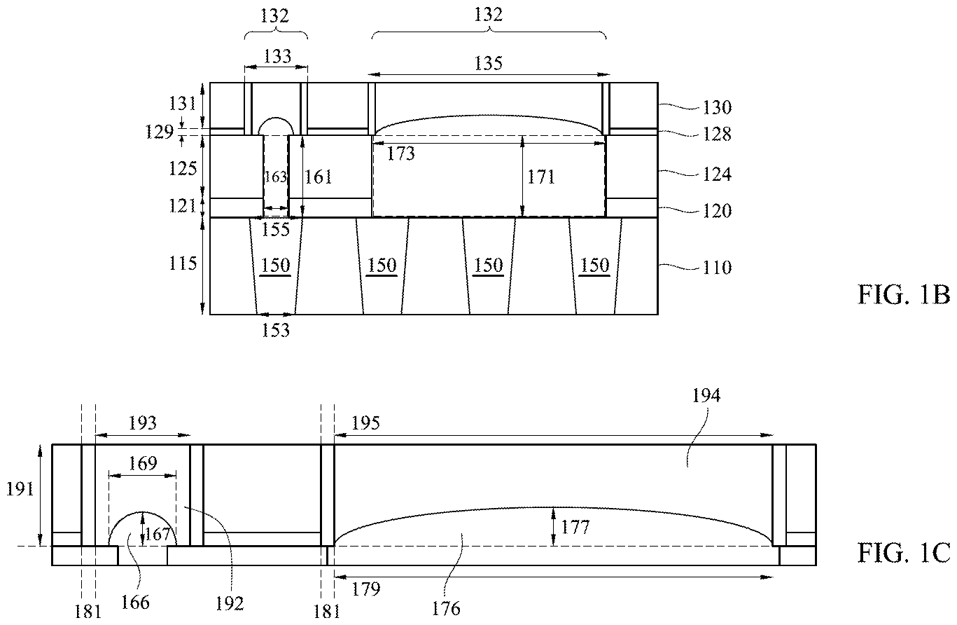

FIG. 1A is an X-axis cross-sectional view showing a first example embodiment of an interconnect structure, in accordance with some embodiments. The interconnect structure is part of an overall semiconductor package, and is discussed herein as being fabricated during a middle-end-of-line (MEOL) process, when local electrical connections are being made between transistors of a semiconductor die. However, the various process steps described herein are also applicable to fabrication of the interconnect structure during the back-end-of-line (BEOL) process when various semiconductor dies are interconnected to form desired electrical circuits

Initially, the semiconductor package 100 includes a semiconductor die 102, upon which the interconnect structure will be built. The die includes a substrate 104 and multiple layers upon the substrate which form an integrated circuit, shown here as one layer 106.

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), or silicon oxynitride (SiOₓN_{y}), where 0<x, y≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

Continuing, the interconnect structure 108 includes a first dielectric layer 110 and a second dielectric layer 124, which are separated by a first etch stop layer 120. The two dielectric layers may independently be considered intermetal dielectric (IMD) layers or interlayer dielectric (ILD) layers. The first dielectric layer 110 may also be considered a pre-metal dielectric (PMD) layer. These two dielectric layers may be at any level of the interconnect layers upon the semiconductor die 102. The first dielectric layer includes a lower surface 112 and an upper surface 114, with the lower surface being closer to the semiconductor die 102 than the upper surface.

Bottom vias 150 extend through the first dielectric layer 110 between the lower surface 112 and the upper surface 114 of the first dielectric layer. As illustrated here, four such bottom vias 150 are present. It is noted that each bottom via may be in the form of a trench extending along the Y-axis, and thus this aspect is not visible.

The second dielectric layer 124 is located above the first dielectric layer 110, and also includes a lower surface 126 and an upper surface 127. Vias 160, 170 (indicated with dashed lines) also extend through the second dielectric layer 124 and the first etch stop layer 120 to contact a bottom via 150. A narrow via 160 and a wide via 170 are illustrated here. The narrow via 160 contacts only one bottom via 150, while the wide via 170 contacts two or more bottom vias 150. Each via also includes a cap 166, 176, which rests upon the upper surface 127 of the second dielectric layer.

A second etch stop layer 128 is present upon the second dielectric layer 124, and a third dielectric layer 130 is present upon the second etch stop layer 128. Gaps 132 are present in the third dielectric layer 130 and the second etch stop layer 128 above the vias 160, 170 and their caps 166, 176. A diffusion barrier layer 180 is present which separates the third dielectric layer 130 from the caps 166, 176. Top vias 192, 194 are present in the gaps above the vias 160, 170. The vias 160, 170 electrically connect one or more bottom vias 150 to a top via 192, 194. It is noted that each top via may be in the form of a trench extending along the Y-axis, and thus this aspect is not visible.

FIG. 1B and FIG. 1C provide additional details about the dimensions of the various components of the interconnect structure.

Referring first to FIG. 1B, in some embodiments, the first dielectric layer 110 has a thickness or depth 115 of about 5 nanometers (nm) to about 50 nm. Thus, the bottom vias 150 may each also have a height or thickness of about 5 nm to about 50 nm. As indicated, each bottom via 150 has a lower width 153 at the lower surface 112, and an upper width 155 at the upper surface 114. In particular embodiments, the upper width 155 is greater than the lower width 153. In particular embodiments, the upper width 155 is from about 5 nm to about 30 nm. In particular embodiments, the lower width 153 is from about 4 nm to about 10 nm. In more specific embodiments, the difference between the upper width and the lower width is from about 1 nm to about 26 nm. Other values and ranges for each of these measurements are also within the scope of this disclosure.

In some embodiments, the first etch stop layer 120 has a thickness 121 of about 3 nm to about 30 nm. In some embodiments, the second dielectric layer 124 has a thickness 125 of about 2 nanometers (nm) to about 40 nm. Other values and ranges for each of these measurements are also within the scope of this disclosure.

The vias 160, 170 extend through the first etch stop layer 120 and the second dielectric layer 124. In some embodiments, each via 160, 170 has a height or thickness 161, 171 of about 5 nm to about 40 nm. Each via 160, 170 also has a width 163, 173, which is generally uniform through the thickness of the second dielectric layer 124. Generally, the width of the via may be from about 4 nm to about 200 nm. For example, the width 163 of the narrow via may be from about 4 nm to about 20 nm. As another example, the width 173 of the wide via may be from about 25 nm to about 200 nm. As illustrated here, the wide via 170 contacts two or more bottom vias 150. In some embodiments, the width 163 of the narrow via is less than the upper width 155 of the bottom via 150, but this is not required. Embodiments are also contemplated where the width 163 of the narrow via is equal to or greater than the upper width 155 of the bottom via. Other values and ranges for each of these measurements are also within the scope of this disclosure.

In some embodiments, the second etch stop layer 128 has a thickness 129 of about 3 nm to about 30 nm. In some embodiments, the third dielectric layer 130 has a thickness 131 of about 2 nanometers (nm) to about 40 nm. Other values and ranges for each of these measurements are also within the scope of this disclosure.

Referring now to the top vias 192, 194, they are formed in gaps 132 in the third dielectric layer 130 and the second etch stop layer 128. Generally, the width of the gap may be from about 10 nm to about 1000 nm. For example, the width 133 of the gap in which the narrow via 160 is exposed may be from about 10 nm to about 30 nm. As another example, the width 135 of the gap in which the wide via 170 is exposed may be from about 30 nm to about 1000 nm. Other values and ranges for each of these measurements are also within the scope of this disclosure.

Referring now to the higher magnification of FIG. 1C, each cap 166, 176, has a height or thickness 167, 177. In specific embodiments, the thickness 167, 177 of the cap is at least 2 nm. In more particular embodiments, the thickness of the cap may be from 2 nm to about 40 nm, or from about 5 nm to about 40 nm, or from about 10 nm to about 40 nm. Each cap 166, 176 also has a width 169, 179, which is measured at the base of the cap where it contacts the via. Generally, the width of the cap may be from about 4 nm to about 1000 nm. For example, the width 169 of the narrow cap may be from about 4 nm to about 30 nm. As another example, the width 179 of the wide cap may be from about 30 nm to about 1000 nm. Other values and ranges for each of these measurements are also within the scope of this disclosure.

The width 169, 179 of the cap is usually greater than the width 163, 173 of the via 160, 170, though this is not required. In particular embodiments, the difference between the cap width 169, 179 and the via width 163, 173 is from about 5 nm to about 800 nm, or from about 5 nm to about 25 nm. Other values and ranges for each of these measurements are also within the scope of this disclosure.

A diffusion barrier layer 180 is present on the sidewalls of each gap. In particular embodiments, the width 181 of the diffusion barrier layer is from about 0.5 nm to about 4 nm. Other values and ranges are also within the scope of this disclosure.

The top vias 192, 194 extend through the second etch stop layer 128 and the third dielectric layer 130. In some embodiments, each top via 192, 194 has a height or thickness 191 of about 5 nm to about 40 nm. The width 193, 195 of the top via corresponds to the width of the gap minus the width of the diffusion barrier layer and whatever additional layers may be added upon the caps 166, 176. Other values and ranges for each of these measurements are also within the scope of this disclosure.

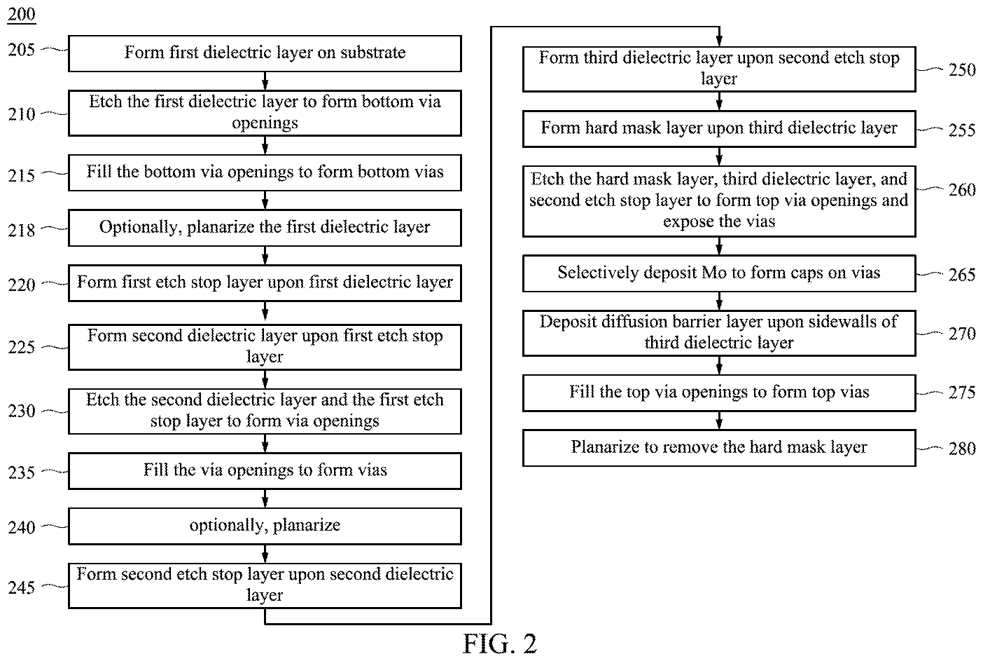

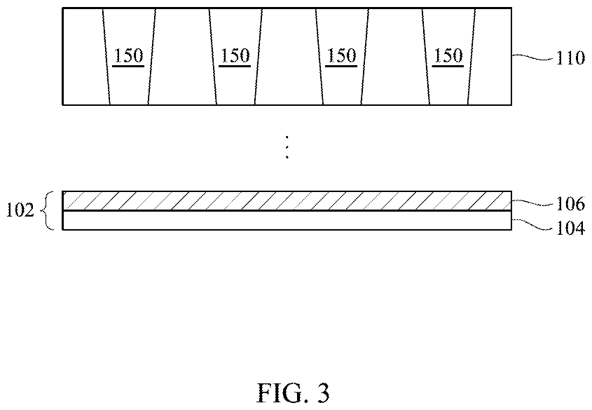

FIG. 2 is a flow chart illustrating a method 200 for making an interconnect structure, in accordance with some embodiments of the present disclosure. Some steps of the method are also illustrated in FIGS. 3-11. These figures provide different views for better understanding. While the method steps are discussed below in terms of forming an interconnect structure with two vias 160, 170, such discussion should also be broadly construed as applying to the formation of only one via or multiple vias concurrently. These method steps may be used during an MEOL or BEOL process.

It is noted that certain conventional steps are not expressly described in the discussion below. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The methods and systems of the present disclosure include several different dielectric layers. These layers can generally be made from any suitable combination of dielectric materials, although the characteristics of any particular layer may also be further defined. Examples of dielectric materials may include silicon dioxide (SiO₂), silicon nitride (Si₃N₄), silicon carbide (SIC), hafnium oxide (HfOₓ), zirconium dioxide (ZrO₂), aluminum oxide (Al₂O₃), aluminum nitride (AlN), silicon carbonitride (SiCₓN_{y}), silicon oxycarbide (SiCₓO_{y}), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN) (where 0<x, y, z≤1, and x+y+z=1). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). Low-k dielectric materials usually have a dielectric constant equal to that or silicon dioxide or lower (i.e. 3.9 or less). High-k dielectric materials usually have a dielectric constant of 7 or higher, or 10 or higher.

Continuing, then, in step 205 of FIG. 2 and as illustrated in FIG. 3, a first dielectric layer 110 is formed upon the substrate 104. (The semiconductor die 102 is omitted in further figures for convenience.) The first dielectric layer is formed from a dielectric material, and is typically formed from materials such as silicon dioxide (SiO₂), silicon nitride (Si₃N₄), aluminum oxide (AlOₓ), aluminum nitride (AlN), hafnium oxide (HfOₓ), silicon carbonitride (SiCₓN_{y}), and silicon oxycarbide (SiCₓO_{y}). The first dielectric layer can be formed by physical vapor deposition (PVD) or chemical vapor deposition (CVD) or other suitable process. For example, a silicon-containing source gas may act as a silicon precursor that reacts with an oxygen-containing source gas. Examples of such silicon precursors include but are not limited to tetraethyl orthosilicate (TEOS), trimethylsilane, tetramethylsilane, and hexachlorodisilane (HCDS). Ozone (O₃) can be used to provide oxygen atoms for the reaction. At temperatures of about 300° C. to about 500° C. or higher, these gases will react to deposit silicon dioxide. The first dielectric layer 110 is then planarized to obtain a flat surface.

A photoresist layer is then applied and patterned. In step 210 of FIG. 2, etching is then performed to form at least one bottom via opening. Usually, a plurality of such bottom via openings are formed in this etching step. In step 215 of FIG. 2, an electrically conductive material is deposited in the bottom via opening(s) to form bottom vias 150. This deposition may be performed before or after the patterned photoresist layer is removed. Examples of suitable electrically conductive materials may include molybdenum, tungsten, copper, cobalt, ruthenium, or titanium nitride (TiN). In particular embodiments, the electrically conductive material is molybdenum (Mo) or tungsten (W), and in more specific embodiments is tungsten. The deposition may be performed by PVD, CVD, sputtering, or other suitable process. Optionally, planarizing may be performed again after the deposition to remove excess electrically conductive material, as indicated in optional step 218. The resulting structure is shown in FIG. 3.

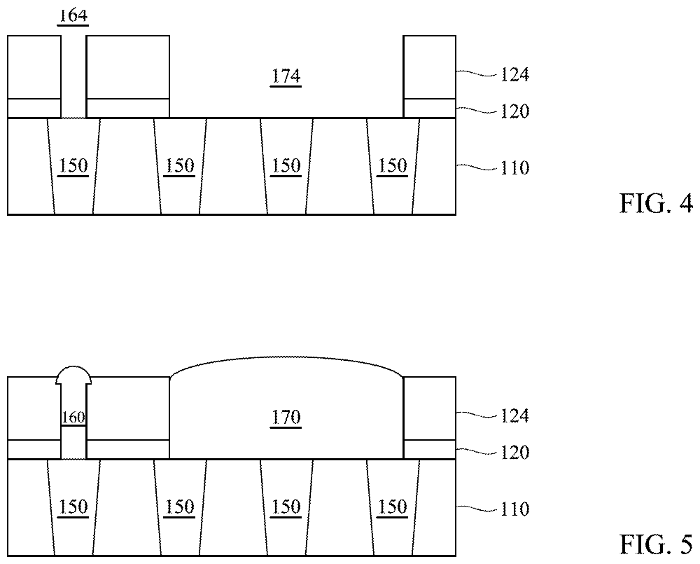

Next, in step 220 of FIG. 2 and as illustrated in FIG. 4, the first etch stop layer 120 is formed upon the first dielectric layer 110. The first etch stop layer is formed from a material that is different from the first dielectric layer, and may be made for example from a dielectric material or a metal oxide. In particular embodiments, the first etch stop layer is formed from silicon nitride. The first etch stop layer may be formed by PVD, CVD, atomic layer deposition (ALD), or other suitable process.

In step 225 of FIG. 2, the second dielectric layer 124 is formed upon the first etch stop layer 120. The second dielectric layer 124 and the first dielectric layer 110 are usually formed from the same material. Again, PVD or CVD is usually used to form this dielectric layer. A photoresist layer is then applied and patterned. In step 230 of FIG. 2, the second dielectric layer 124 and the first etch stop layer 120 are etched to form via openings 164, 174. Each via opening contacts one or more bottom vias 150. The patterned photoresist layer is then removed.

The resulting structure is illustrated in FIG. 4. Two different via openings are illustrated here, a narrow via opening 164 and a wide via opening 174. The narrow via opening 164 contacts only one bottom via 150, while the wide via opening 174 contacts two or more bottom vias 150.

Next, in step 235 of FIG. 2 and as illustrated in FIG. 5, the via openings 164, 174 are filled with an electrically conductive material to form a via 160, 170. In particular embodiments, the electrically conductive material is molybdenum (Mo).

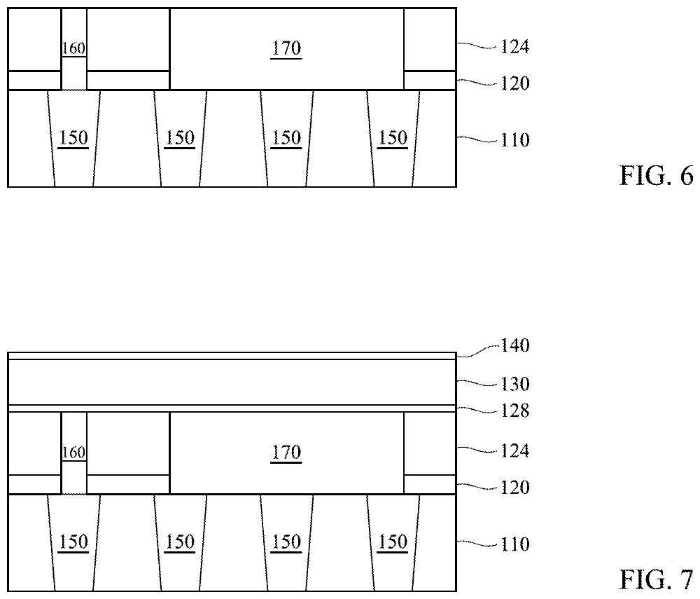

In FIG. 5, the vias 160, 170, are shown as having a rough surface that is not flat. As indicated in optional step 240 of FIG. 2, planarizing may be performed again after the deposition to remove excess electrically conductive material. The resulting structure is shown in FIG. 6.

In following step 245 of FIG. 2 and as illustrated in FIG. 7, a second etch stop layer 128 is formed upon the second dielectric layer 124. The second etch stop layer is formed from a material that is different from the second dielectric layer. The second etch stop layer is also usually formed from a material that is different from the first etch stop layer. Again, the second etch stop layer may be made for example from a dielectric material or a metal oxide. The second etch stop layer may be formed by PVD, CVD, atomic layer deposition (ALD), or other suitable process.

Next, in step 250 of FIG. 2, a third dielectric layer 130 is formed upon the second etch stop layer 128. The third dielectric may be formed by PVD, CVD, or other suitable process. In particular embodiments, the third dielectric layer is formed from a low-k dielectric material.

Then, in step 255 of FIG. 2, a hard mask layer 140 is formed upon the third dielectric layer 130. In particular embodiments, the hard mask layer is formed from a tungsten-doped carbide (WdC). The hard mask layer may be formed by PVD, CVD, atomic layer deposition (ALD), or other suitable process. The resulting structure is illustrated in FIG. 7.

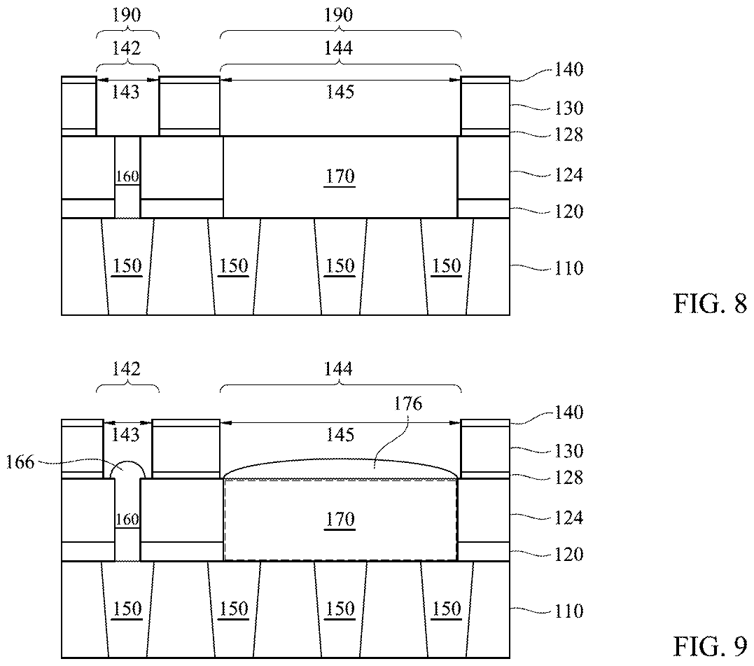

A photoresist layer is then applied and patterned. Next, in step 260 of FIG. 2 and as illustrated in FIG. 8, the hard mask layer 140, the third dielectric layer 130, and the second etch stop layer 128 are etched to form top via openings 190. Each top via opening exposes a via 160, 170 passing through the second dielectric layer 124. The patterned photoresist layer is then removed. The hard mask layer 140 may be referred to as having windows 142, 144 through which the vias 160, 170 are exposed. The windows have a width 143, 145.

Next, in step 265 of FIG. 2 and as illustrated in FIG. 9, molybdenum is selectively deposited to form a molybdenum cap 166, 176 upon each via 160, 170. Significantly, molybdenum is not deposited upon the hard mask layer 140 or the sides of the hard mask layer in the windows 142, 144. Thus, the width 143, 145 of the windows is not reduced. The interface between the via and the cap is desirably homogeneous, i.e. they are made of the same material.

In particular embodiments, the selective deposition is performed by CVD. In CVD, volatile precursors react and/or decompose to produce the desired deposit. In the present disclosure, a mixture of a carrier gas and a molybdenum precursor are used. The carrier gas may be, for example, hydrogen (H₂). Examples of molybdenum precursors include MoCl₅, MoO₃, Mo(CO)₆, MoO₂Cl₂, and ammonium heptamolybdate. In particular embodiments, the molybdenum precursor used is MoCl₅. The deposition time, in some particular embodiments, is from about 180 second to about 240 seconds.

In further particular embodiments, the atomic or molar ratio between the carrier gas and the molybdenum precursor is about 2000:1 or lower (for example 1500:1 would be considered a lower ratio). For clarity, in the gas mixture, the carrier gas is always present in a greater molar amount than the molybdenum precursor. At ratios higher than about 2000:1, molybdenum also deposits on the hard mask layer, which reduces the width 143, 145 of the windows 142, 144 in the hard mask layer and increases the risk of creating voids. In more specific embodiments, the molar ratio is about 1900:1 or lower, or about 1500:1 or lower. In this regard, without being bound by theory, it is believed that at higher concentrations of the molybdenum precursor, the absorption rate of Mo onto the WdC hard mask layer is reduced so that nucleation does not occur and Mo does not deposit on the hard mask layer. Concurrently, the growth rate of the cap upon the via is increased due to the increased molybdenum concentration.

It is noted that the caps are illustrated as having a dome shape. This occurs because the CD of the top via opening is greater than the CD of the via. As a result, deposition occurs in all directions, rather than uniformly across the width of the top via opening.

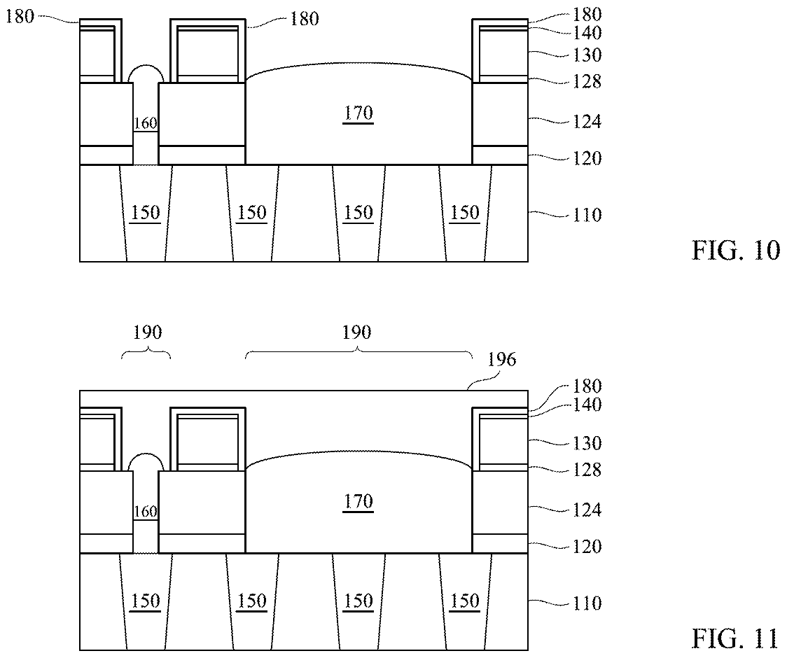

Continuing, in step 270 of FIG. 2 and as illustrated in FIG. 10, a diffusion barrier layer 180 is deposited around each cap 166, 176. This layer reduces or prevents diffusion of the top via material into the third dielectric layer. Examples of suitable diffusion barrier material such as titanium nitride (TIN), tantalum nitride (TaN), indium oxide (In₂O₃), tungsten nitride, tungsten silicide, cobalt, ruthenium, or tantalum. It is noted that some of these materials are actually ceramics, but are considered “barrier metals” by one of ordinary skill in the art because they have the common functional property of chemically isolating two materials on opposite sides while still being electrically conductive. In specific embodiments, the diffusion barrier material used is TaN. This layer can be formed using a process such as ALD. It should also be noted that the diffusion barrier layer is applied to the third dielectric material, and is desirably not deposited upon the cap 166, 176 (although small amounts may land upon the perimeter of the cap). The diffusion barrier layer 180 may also be present upon the hard mask layer 140.

Continuing, in step 275 of FIG. 2 and as illustrated in FIG. 11, the top via openings or gaps 190 are filled with an electrically conductive material 196. This may be performed via PVD, CVD, sputtering, or other suitable process. Because the windows 142, 144 of the hard mask layer 140 are not reduced in width, the risk of creating voids is reduced or avoided. Materials may include copper, molybdenum, cobalt, ruthenium or tungsten. In particular embodiments, copper is used to fill the top via openings. As seen in FIG. 11, excess material may be deposited upon the substrate and upon the hard mask layer 140.

In step 280 of FIG. 2, the substrate is planarized. Referring to FIG. 11, the hard mask layer 140 and excess diffusion barrier material and top via material deposited thereon are removed. Top vias 192, 194 are thus formed. The resulting structure is shown in FIG. 1A.

The methods and systems of the present disclosure are advantageous. The via contact area can be increased, which reduces the total interconnect resistance. The thickness of the metal cap can be increased from 2 nanometers to tens of nanometers, thus increasing the via contact area. This can be achieved without degrading the gapfill window for the deposition step that forms the top vias, thus reducing or avoiding the formation of voids in the top vias. In some particular embodiments, the total interconnect resistance can be reduced from 80 ohms to about 60 ohms (the kelvin contact resistance of via on trench interconnect). The interconnect structure is also suitable for use with transistors of any pitch, and is compatible with other interconnect layers and power rails formed on the backside of the wafer substrate.

Additional processing steps may be performed to obtain devices with semiconductor packages containing the interconnect structure. Those semiconductor packages might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

Some aspects of the present disclosure thus relate to methods for forming a molybdenum cap upon a via. A hard mask layer is patterned to expose the via through a window. The molybdenum cap is deposited upon the via using a mixture comprising a carrier gas and a molybdenum precursor. Molybdenum is not deposited upon the hard mask layer, so that the width of the window in the hard mask layer is not reduced in size.

Also disclosed herein in various embodiments are methods for forming an interconnect structure on a substrate. A first dielectric layer is formed upon the substrate. The first dielectric layer is etched to form at least one bottom via opening. An electrically conductive material is deposited in the at least one bottom via opening. The substrate is then planarized to obtain at least one bottom via. A first etch stop layer is formed upon the first dielectric layer. A second dielectric layer is formed upon the etch stop layer. The second dielectric layer and the etch stop layer are etched to form at least one via opening to the at least one bottom via. An electrically conductive material is deposited in the at least one via opening. The first dielectric layer is then planarized to obtain a via. A second etch stop layer is formed upon the second dielectric layer. A third dielectric layer is formed upon the second etch stop layer. A hard mask layer is formed upon the third dielectric layer. The hard mask layer, the third dielectric layer, and the second etch stop layer are etched to form a top via opening that exposes the via. Molybdenum is selectively deposited upon the exposed via to form a cap. A diffusion barrier layer is deposited around the cap. The top via opening is filled with an electrically conductive material. The third dielectric layer is then planarized to obtain top vias and form the interconnect structure.

Also disclosed herein in various embodiments are interconnect structures that include a via passing through a dielectric layer. A cap is present upon the via. The cap has a thickness of at least 2 nanometers.

Also disclosed herein are semiconductor packages that contain the interconnect structure. Such packages usually also include an integrated circuit (IC). Devices including such semiconductor packages are also contemplated, such as display panel drivers, image sensors, mobile telephones, facial recognition systems, motion sensors, power management devices, and/or image signal processors.

The methods, systems, and devices of the present disclosure are further illustrated in the following non-limiting working example, it being understood that the example is intended to be illustrative only and that the disclosure is not intended to be limited to the materials, conditions, process parameters and the like recited herein.

### EXAMPLES

Experiments were conducted using a hard mask of WdC and deposition upon a via made of molybdenum. A gas mixture of H₂/MoCl₅ was used for CVD. When the gas ratio of H₂/MoCl₅ was 3859, a molybdenum layer with a thickness of about 70 angstroms formed on the WdC hard mask, reducing the width of the window above the via. When the gas ratio was 1900 and the deposition time was 210 seconds, no molybdenum layer formed on the WdC hard mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a molybdenum cap upon a via, comprising:
patterning a hard mask layer to expose the via through a window;
depositing the molybdenum cap upon the via using a mixture comprising a carrier gas and a molybdenum precursor;
wherein molybdenum is not deposited upon the hard mask layer, so that a width of the window in the hard mask layer is not reduced in size.

2. The method of claim 1, where a molar ratio between the carrier gas and the molybdenum precursor is about 2000:1 or lower.

3. The method of claim 1, wherein the carrier gas is hydrogen (H₂).

4. The method of claim 1, wherein the molybdenum precursor is MoCl₅.

5. The method of claim 1, wherein the via has a width of about 5 nanometers to about 30 nanometers.

6. The method of claim 1, wherein the molybdenum cap upon the via has a thickness of at least 2 nanometers.

7. The method of claim 1, wherein the molybdenum cap upon the via has a width of about 3 nanometers to about 200 nanometers.

8. The method of claim 1, wherein the gap has a width of about 5 nanometers to about 30 nanometers.

9. The method of claim 1, wherein the via contacts one or more bottom vias.

10. The method of claim 1, further comprising depositing a diffusion barrier layer around the molybdenum cap.

11. The method of claim 1, further comprising forming a top via upon the molybdenum cap.

12. An interconnect structure, comprising:
a molybdenum via passing through a dielectric layer;
a molybdenum cap upon the molybdenum via, where the cap has a thickness of at least 2 nanometers.

13. The interconnect structure of claim 12, wherein the via has a width of about 4 nanometers to about 200 nanometers.

14. The interconnect structure of claim 12, wherein the cap has a width of about 3 nanometers to about 200 nanometers.

15. The interconnect structure of claim 12, wherein the cap has a thickness of at least 2 nanometers to about 40 nanometers.

16. The interconnect structure of claim 12, wherein the dielectric layer comprises a silicon oxide, silicon nitride, an aluminum oxide, aluminum nitride, hafnium oxide, silicon carbonitride, or silicon oxycarbide.

17. The interconnect structure of claim 12, further comprising a diffusion barrier layer around the molybdenum cap.

18. The interconnect structure of claim 12, wherein the molybdenum via connects a bottom via and a top via.

19. A method for forming an interconnect structure, comprising:
forming a first dielectric layer upon a substrate;
etching the first dielectric layer to form at least one bottom via opening;
depositing an electrically conductive material in the at least one bottom via opening;
planarizing the first dielectric layer to obtain at least one bottom via;
forming a first etch stop layer upon the first dielectric layer;
forming a second dielectric layer upon the etch stop layer;
etching the second dielectric layer and the etch stop layer to form at least one via opening to the at least one bottom via;
depositing an electrically conductive material in the at least one via opening;
planarizing the second dielectric layer to obtain a via;
forming a second etch stop layer upon the second dielectric layer;
forming a third dielectric layer upon the second etch stop layer;
forming a hard mask layer upon the third dielectric layer;
etching the hard mask layer, the third dielectric layer, and the second etch stop layer to form a top via opening that exposes the via;
selectively depositing molybdenum upon the exposed via to form a cap;
depositing a diffusion barrier layer around the cap;
filling the top via opening with an electrically conductive material; and
planarizing the third dielectric layer to form the interconnect structure.

20. The method of claim 19, wherein the cap is formed using a mixture of H₂ and MoCl₅ with a molar ratio (H₂:MoCl₅) of 1500:1 or lower.
